(19) United States
(12) Patent Application Publication
(10) Pub. No.: US 2026/0153679 A1
(43) Pub. Date: Jun. 4, 2026

(54) PACKAGE STRUCTURE

(71) Applicant: Advanced Semiconductor Engineering, Inc., Kaohsiung (TW)

(72) Inventor: Ying-Chung CHEN, Kaohsiung (TW)

(73) Assignee: Advanced Semiconductor Engineering, Inc., Kaohsiung (TW)

(21) Appl. No.: 18/966,058

(22) Filed: Dec. 2, 2024

(51) Int. Cl. G02B 6/26; G02B 1/00; H01L 25/16

(52) U.S. Cl. CPC G02B 6/262; G02B 1/002; H10W 90/00

(57) ABSTRACT

A package structure is provided. The package structure includes a first photonic component, a second photonic component, and an optical connector. The optical connector includes a first metasurface and a second metasurface opposite to the first metasurface. The optical connector is configured to optically couple the first photonic component to the second photonic component.

### BACKGROUND

### 1. Technical Field

The present disclosure relates generally to a package structure.

### 2. Description of the Related Art

Currently, optical signals are transmitted to or from a photonic component through an optical connector including waveguides manufactured in a glass plate and various mechanical connecting elements. Such optical connector includes a complicated structure. Therefore, miniaturization of the optical connector is difficult, and manufacturing processes of the optical connector are complicated.

### SUMMARY

In one or more arrangements, a package structure includes a first photonic component, a second photonic component, and an optical connector. The optical connector includes a first metasurface and a second metasurface opposite to the first metasurface. The optical connector is configured to optically couple the first photonic component to the second photonic component.

In one or more arrangements, a package structure includes a first photonic component, a second photonic component, and an optical connector. The first photonic component includes a first optical channel. The second photonic component includes a second optical channel that is misaligned with the first optical channel. The optical connector includes a first optical structure and a second optical structure. Each optical structure is configured to focus or collimate an optical signal transmitted between the first optical channel and the second optical channel.

In one or more arrangements, a package structure includes a first optical component, a second optical component, and an optical connector. The optical connector includes a homogeneous medium. The homogeneous medium is configured to transmit a plurality of optical signals between the first optical component and the second optical component.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1A is a cross-section of a package structure in accordance with some arrangements of the present disclosure.

FIG. 1B is a top view of a package structure in accordance with some arrangements of the present disclosure.

FIG. 2A is a cross-section of a portion of a package structure in accordance with some arrangements of the present disclosure.

FIG. 2B is a top view of a portion of a package structure in accordance with some arrangements of the present disclosure.

FIG. 2C is a cross-section of a portion of a package structure in accordance with some arrangements of the present disclosure.

FIG. 2D is a top view of a portion of a package structure in accordance with some arrangements of the present disclosure.

FIG. 3A is a cross-section of a package structure in accordance with some arrangements of the present disclosure.

FIG. 3B is a top view of a package structure in accordance with some arrangements of the present disclosure.

FIG. 4A is a cross-section of a package structure in accordance with some arrangements of the present disclosure.

FIG. 4B is a top view of a package structure in accordance with some arrangements of the present disclosure.

FIG. 5A is a cross-section of a package structure in accordance with some arrangements of the present disclosure.

FIG. 5B is a top view of a package structure in accordance with some arrangements of the present disclosure.

FIG. 6A is a cross-section of a package structure in accordance with some arrangements of the present disclosure.

FIG. 6B is a top view of a package structure in accordance with some arrangements of the present disclosure.

FIG. 7A is a cross-section of a package structure in accordance with some arrangements of the present disclosure.

FIG. 7B is a top view of a package structure in accordance with some arrangements of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

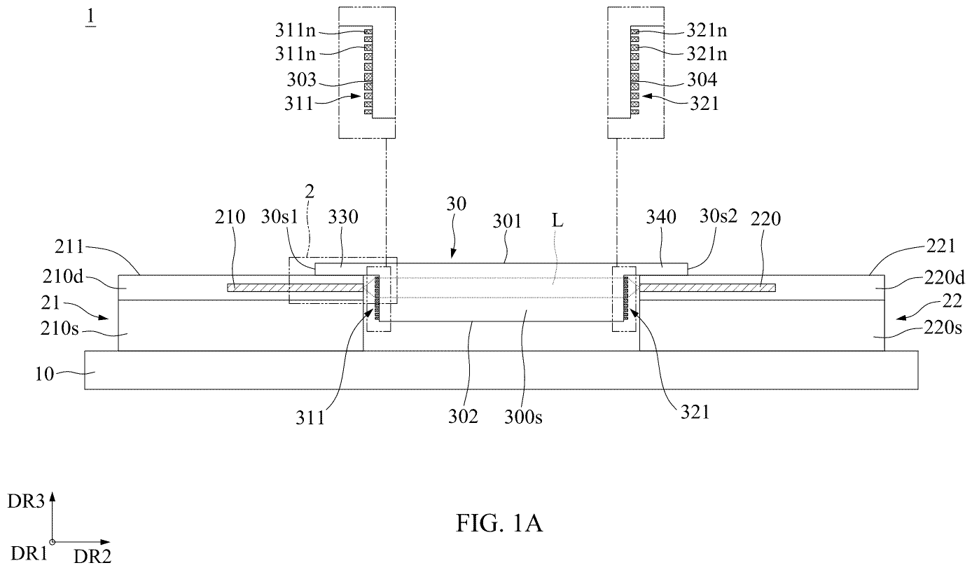

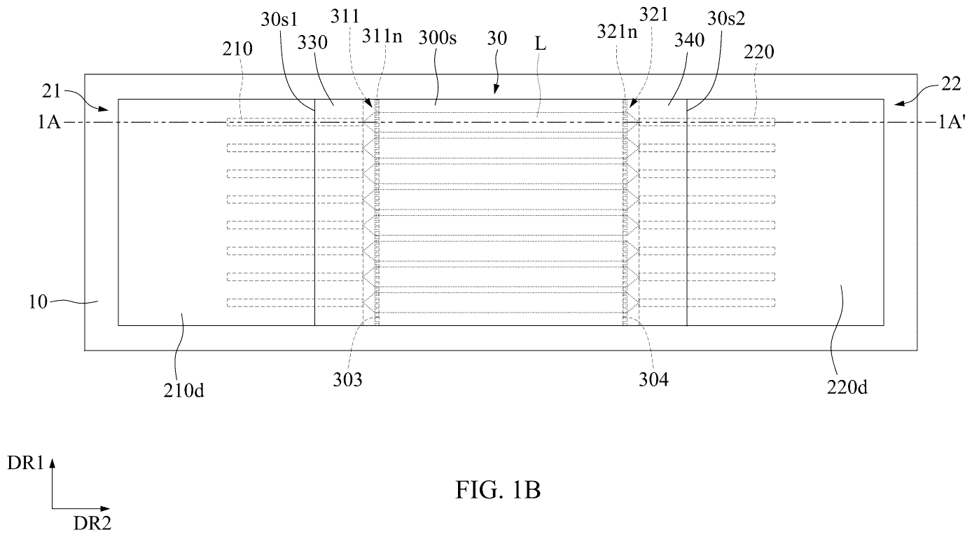

FIG. 1A is a cross-section of a package structure 1 in accordance with some arrangements of the present disclosure. FIG. 1B is a top view of a package structure 1 in accordance with some arrangements of the present disclosure. In some arrangements, FIG. 1A is a cross-section along a line 1A-1A′ in FIG. 1B. The package structure 1 may include a substrate 10, optical components (e.g., photonic components 21 and 22), and an optical connector 30.

The substrate 10 may include, for example, a printed circuit board, such as a paper-based copper foil laminate, a composite copper foil laminate, or a polymer-impregnated glass-fiber-based copper foil laminate. The substrate 10 may include an interconnection structure, such as a plurality of conductive traces and/or a plurality of conductive vias. In some arrangements, the substrate 10 includes a ceramic material, a metal plate, an organic substrate, or a leadframe. In some arrangements, the substrate 10 may include a two-layer substrate which includes a core layer and a conductive material and/or structure disposed on an upper surface and a bottom surface of the substrate 10. The conductive material and/or structure may include a plurality of conductive traces. The substrate 10 may be referred to as a carrier. The substrate 10 may include one or more electronic components, e.g., electronic integrated circuits (EIC).

The photonic components 21 and 22 may be disposed over the substrate 10. In some arrangements, the photonic components 21 and 22 are electrically connected to the substrate 10, e.g., the electronic components (or EICs) of the substrate 10.

In some arrangements, the photonic component 21 includes a base layer 210s, a dielectric structure 210d, and one or more optical channels 210. The photonic component 21 may further include one or more circuit layers and one or more conductive pads electrically connected to the circuit layers. The circuit layers may include various photonic devices, e.g., a PIC, a photodetector, a photodiode, a SOA, an optical modulator, or a combination thereof. In some arrangements, the base layer 210s may be or include a semiconductor substrate, e.g., a silicon substrate. In some arrangements, the dielectric structure 210d includes a plurality of dielectric layers. In some arrangements, the optical channel 210 is or includes an optical waveguide. The optical channel 210 may be embedded in the dielectric structure 210d and disposed between the dielectric layers. In some arrangements, an end or a terminal of the optical channel 210 is exposed from the dielectric structure 210d. In some arrangements, an end or a terminal of the optical channel 210 is exposed by a lateral surface of the photonic component 21. The optical channels 210 may extend in a direction DR2 substantially parallel to the upper surface 211. The optical channels 210 may be arranged in a row in a direction DR1 substantially perpendicular to the direction DR2. The photonic component 21 may have an upper surface 211 facing away from the substrate 10.

In some arrangements, the photonic component 22 includes a base layer 220s, a dielectric structure 220d, and one or more optical channels 220. The photonic component 22 may further include one or more circuit layers and one or more conductive pads electrically connected to the circuit layers. The circuit layers may include various photonic devices, e.g., a PIC, a photodetector, a photodiode, a SOA, an optical modulator, or a combination thereof. In some arrangements, the base layer 220s may be or include a semiconductor substrate, e.g., a silicon substrate. In some arrangements, the dielectric structure 220d includes a plurality of dielectric layers. In some arrangements, the optical channel 220 is or includes an optical waveguide. The optical channel 220 may be embedded in the dielectric structure 220d and disposed between the dielectric layers. In some arrangements, an end or a terminal of the optical channel 220 is exposed from the dielectric structure 220d. In some arrangements, an end or a terminal of the optical channel 220 is exposed by a lateral surface of the photonic component 22. The photonic component 22 may have an upper surface 221 facing away from the substrate 10.

The optical connector 30 may be disposed between the photonic components 21 and 22. The optical connector 30 may be referred to as an optical director or an optical interconnector. The optical connector 30 may be configured to optically couple the photonic component 21 to the photonic component 22 or the photonic component 22 to the photonic component 21. The optical connector 30 may have an upper surface 301 (or a top surface), a lower surface 302 (or a bottom surface), and lateral surfaces 303 and 304. In some arrangements, the optical connector 30 includes a base 300s and extensions 330 and 340.

In some arrangements, the base 300s is or includes a transparent base. The base 300s may be configured to transmit one or more optical signals L between the photonic components 21 and 22. The optical signals L may be light or beams of light. The optical signals L may be substantially collimated lights, substantially collimated beams of light, divergent lights, divergent beams of light, convergent lights, and/or convergent beams of light. The base 300s may be transparent (e.g., having a transmission of about 80% or higher) to the optical signals L. In some arrangements, the base 300s is or includes a homogeneous medium configured to transmit one or more optical signals L between the photonic components 21 and 22. In some arrangements, the optical channels 210 and the optical channels 220 are configured to transmit the optical signals L to or from the homogeneous medium (e.g., the base 300s). In some arrangements, the base 300s has a substantially uniform refractive index within the base 300s (or the homogeneous medium). In some arrangements, the base 300s (or the homogeneous medium) is an integral layer and free of any optical waveguide. In some arrangements, the base 300s (or the homogeneous medium) has a substantially flat coupling surface (e.g., the lateral surface 303) facing the photonic component 21 and a substantially flat coupling surface (e.g., the lateral surface 304) facing the photonic component 22.

In some arrangements, the extension 330 is supported by the photonic component 21, and the extension 340 is supported by the photonic component 22. In some arrangements, the extension 330 has the upper surface 301 and is supported by the upper surface 201 of the photonic component 21. In some arrangements, the extension 340 has the upper surface 301 and is supported by the upper surface 221 of the photonic component 22. In some arrangements, the extensions 330 and 340 are connected to the base 300s. The optical connector 30 including the base 300s and the extensions 330 and 340 may be a monolithic structure or an integral piece, e.g., formed integrally. In some arrangements, the base 300s and the extensions 330 and 340 as a whole may have a substantially uniform refractive index. In some arrangements, the base 300s and the extensions 330 and 340 as a whole may be an integral layer (or a monolithic structure) and free of any optical waveguide formed or disposed therewithin. In some arrangements, the extension 330 overlaps the optical channel 210 in a direction DR3 substantially perpendicular to the upper surface 211 of the photonic component 21. In some arrangements, the extension 340 overlaps the optical channel 220 in the direction DR3.

In some arrangements, the optical connector 30 includes metasurface structures 311 and 321. The metasurface structures 311 and 321 may be referred to as metasurfaces or optical structures. In some arrangements, the metasurface structure 311 is opposite to the metasurface structure 321. In some arrangements, the metasurface structures 311 and 321 are configured to optically couple the photonic component 21 to the photonic component 22 or the photonic component 22 to the photonic component 21. In some arrangements, the metasurface structure 311 faces the photonic component 21, and the metasurface structure 321 faces the photonic component 22. In some arrangements, the base 300s (or the homogeneous medium) has a substantially flat coupling surface (e.g., the metasurface structure 311) facing the photonic component 21 and a substantially flat coupling surface (e.g., the metasurface structure 321) facing the photonic component 22. In some arrangements, the base 300s does not have convex curved coupling surfaces facing the photonic components 21 and 22.

In some arrangements, the metasurface structure 311 (or the optical structure) includes a collimation optics, a focusing optics, or a combination thereof. In some arrangements, the metasurface structure 311 may be configured to switch a divergent light to a substantially collimated light. In some arrangements, the metasurface structure 311 may be configured to switch a divergent beam or a divergent beam of light to a substantially collimated beam of light. In some arrangements, the metasurface structure 311 may be configured to switch a substantially collimated light to a divergent light. In some arrangements, the metasurface structure 311 may be configured to switch a substantially collimated beam or a substantially-collimated beam of light to a divergent beam or a divergent beam of light. In some arrangements, the metasurface structure 311 may be configured to switch a substantially collimated light to a convergent light. In some arrangements, the metasurface structure 311 may be configured to switch a substantially collimated beam or a substantially collimated beam of light to a convergent beam or a convergent beam of light. In some arrangements, the metasurface structure 311 may be configured to switch a convergent light to a substantially collimated light. In some arrangements, the metasurface structure 311 may be configured to switch a convergent beam or a convergent beam of light to a substantially-collimated beam or a substantially-collimated beam of light.

In some arrangements, the metasurface structure 311 (or the metasurface) includes a plurality of nanostructures 311n protruding toward the photonic component 21. The nanostructures 311n may be or include nano-pillars. The nanostructures 311n may be of different dimensions (e.g., diameters, widths, surface areas, or the like). The nanostructures 311n may be formed or disposed on the lateral surface 303. The nanostructures 311n may protrude from the lateral surface 303. In some arrangements, a nano-film may be deposited on an external surface of the base 300s, and the nano-film may be etched to form a plurality of nanostructures 311n. The nanostructures 311n may be disposed on and/or partially embedded in the base 300s. The nanostructures 311n may have different dimensions. The dimensions of the nanostructures 311n may depend on the light radius received by or transmitted from the optical channels 210. For example, an arrangement of features of the metasurface structure 311 (or the nanostructures 311n) may match a wavelength of the optical signal(s). In some arrangements, the metasurface structure 311 and the base 300s may include or be made of the same material, e.g., silicon oxide, glass, or other suitable materials. In some arrangements, the inner portion of the nanostructures 311n may have dimensions greater than those of the outer portion of the nanostructures 311n. In some arrangements, the pitch of the inner portion of the nanostructures 311n may be equal to that of the outer portion of the nanostructures 311n. In some arrangements, the space between the inner portion of the nanostructures 311n may be less than that of the outer portion of the nanostructures 311n.

In some arrangements, the metasurface structure 321 (or the optical structure) includes a collimation optics, a focusing optics, or a combination thereof. In some arrangements, the metasurface structure 321 may be configured to switch a divergent light to a substantially collimated light. In some arrangements, the metasurface structure 321 may be configured to switch a divergent beam or a divergent beam of light to a substantially collimated beam of light. In some arrangements, the metasurface structure 321 may be configured to switch a substantially collimated light to a divergent light. In some arrangements, the metasurface structure 321 may be configured to switch a substantially collimated beam or a substantially-collimated beam of light to a divergent beam or a divergent beam of light. In some arrangements, the metasurface structure 321 may be configured to switch a substantially collimated light to a convergent light. In some arrangements, the metasurface structure 321 may be configured to switch a substantially collimated beam or a substantially collimated beam of light to a convergent beam or a convergent beam of light. In some arrangements, the metasurface structure 321 may be configured to switch a convergent light to a substantially collimated light. In some arrangements, the metasurface structure 321 may be configured to switch a convergent beam or a convergent beam of light to a substantially-collimated beam or a substantially-collimated beam of light.

In some arrangements, the metasurface structure 321 (or the metasurface) includes a plurality of nanostructures 321n protruding toward the photonic component 22. The nanostructures 321n may be or include nano-pillars. The nanostructures 321n may be of different dimensions (e.g., diameters, widths, surface areas, or the like). The nanostructures 321n may be formed or disposed on the lateral surface 304. The nanostructures 321n may protrude from the lateral surface 304. In some arrangements, a nano-film may be deposited on an external surface of the base 300s, and the nano-film may be etched to form a plurality of nanostructures 321n. The nanostructures 321n may be disposed on and/or partially embedded in the base 300s. The nanostructures 321n may have different dimensions. The dimensions of the nanostructures 321n may depend on the light radius received by or transmitted from the optical channels 220. For example, an arrangement of features of the metasurface structure 321 (or the nanostructures 321n) may match a wavelength of the optical signal(s). In some arrangements, the metasurface structure 321 and the base 300s may include or be made of the same material, e.g., silicon oxide, glass, or other suitable materials. In some arrangements, the inner portion of the nanostructures 321n may have dimensions greater than those of the outer portion of the nanostructures 321n. In some arrangements, the pitch of the inner portion of the nanostructures 321n may be equal to that of the outer portion of the nanostructures 321n. In some arrangements, the space between the inner portion of the nanostructures 321n may be less than that of the outer portion of the nanostructures 321n.

According to some arrangements of the present disclosure, the metasurface structures 311 and 321 of the optical connector 30 face the photonic components 21 and 22 and are configured to optically couple the photonic components 21 and 22. The optically coupling surfaces formed of metasurface structures 311 and 321 are substantially flat compared to convex curved lenses, the distance between the photonic components 21 and 22 can be reduced, and thus the optical transmission path between the photonic components 21 and 22 can be reduced, which is advantageous to increasing the transmission speed.

In addition, according to some arrangements of the present disclosure, the optical connector 30 does not include any optical waveguide, and multiple optical signals L are transmitted through a homogeneous medium (e.g., the base 300s). Therefore, the structure of the optical connector 30 for optically coupling the photonic components 21 and 22 is simplified, the manufacturing process of the optical connector 30 is simplified, and the cost is reduced.

Moreover, according to some arrangements of the present disclosure, the metasurface structures 311 and 321 and the base 300s are formed integrally. Therefore, the process is simplified, and the optically coupling structures (e.g., the metasurface structures 311 and 321) for the photonic components 21 and 22 can be disposed in a single operation. The process can be further simplified.

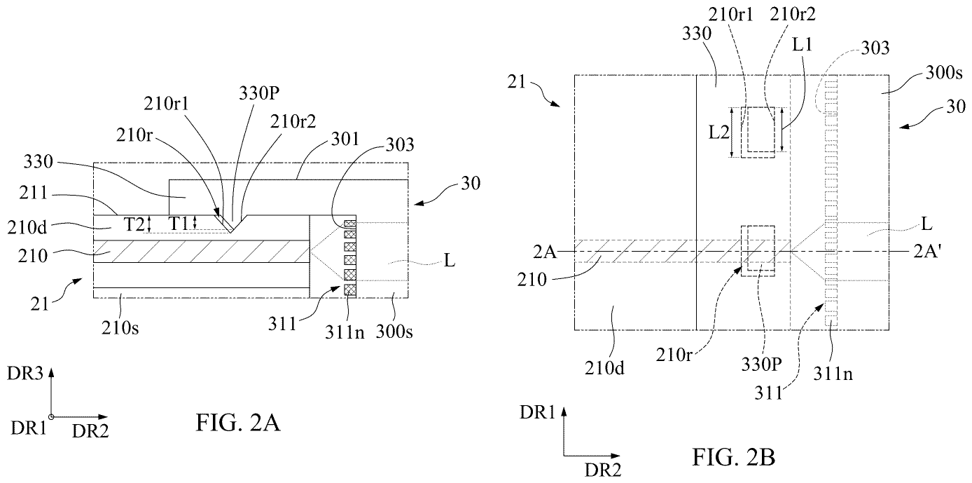

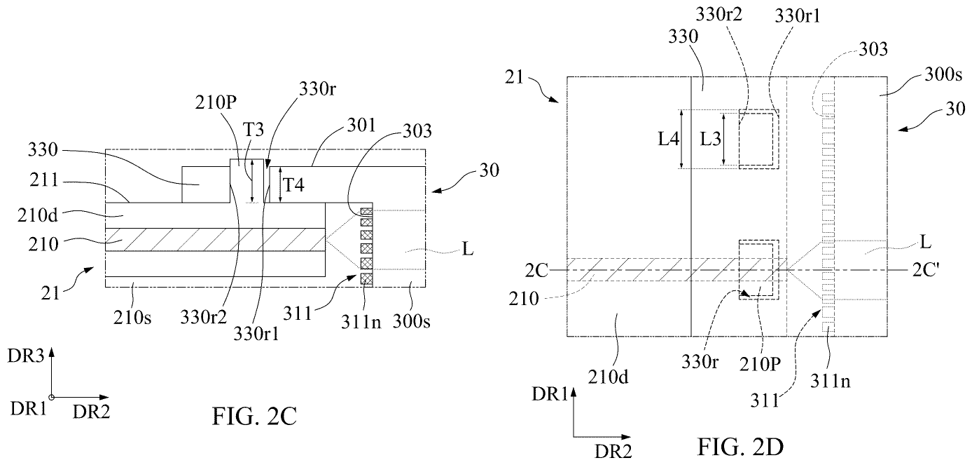

FIG. 2A is a cross-section of a portion 2 of a package structure 1 in accordance with some arrangements of the present disclosure. FIG. 2B is a top view of a portion 2 of a package structure 1 in accordance with some arrangements of the present disclosure. In some arrangements, FIG. 2A is a cross-section along a line 2A-2A′ in FIG. 2B.

In some arrangements, the extension 330 includes a protrusion 330P, and the photonic component 21 includes a recess 210r configured to engage with the protrusion 330P. The dielectric structure 210d may define the recess 210r. In some arrangements, a thickness T1 of the protrusion 330P is less than a depth T2 of the recess 210r. In some arrangements, a length L1 of the protrusion 330P is less than a length L2 of the recess 210r. In some arrangements, the recess 210r is defined by surfaces 210r1 and 210r2. The protrusion 330P may be guided by the surfaces 210r1 and/or 210r2 to slide into the recess 210r to be engaged with the recess 210r. In some arrangements, the protrusion 330P is disposed on and contacting one of the surfaces 210r1 and 210r2 to engage with the recess 210r and allow the bottom surface of the protrusion 330P to contact and abut against the upper surface 211 of the photonic component 21.

The extension 340 may include a protrusion similar to the protrusion 330P, and the photonic component 22 may include a recess similar to the recess 210r to engage with the protrusion of the extension 340.

According to some arrangements of the present disclosure, with the above design of protrusions 330P engaged with the recesses 210r, the optical connector 30 can be passively aligned with the optical channels 210 and 220 without performing an active alignment. In addition, according to some arrangements of the present disclosure, the protrusions 330P are formed integrally with the base 300s of the optical connector 30. Therefore, the process is simplified.

FIG. 2C is a cross-section of a portion 2 of a package structure 1 in accordance with some arrangements of the present disclosure. FIG. 2D is a top view of a portion 2 of a package structure 1 in accordance with some arrangements of the present disclosure. In some arrangements, FIG. 2C is a cross-section along a line 2C-2C′ in FIG. 2D.

In some arrangements, the extension 330 defines an opening 330r (also referred to as “a through hole”), and the photonic component 21 includes a protrusion 210P configured to engage with the opening 330r. In some arrangements, a depth T4 of the opening 330r is less than a thickness T3 of the protrusion 210P. The depth T4 may substantially equal to or greater than the thickness T3 of the protrusion 210P. In some arrangements, a length L3 of the protrusion 210P is less than a length L4 of the opening 330r. In some arrangements, the opening 330r is defined by at least surfaces 330r1 and 330r2 from a cross-sectional view perspective. The protrusion 210P may be guided by the surfaces 330r1 and/or 330r2 to slide into the opening 330r to be engaged with the opening 330r. In some arrangements, the protrusion 330P is disposed on and contacting one of the surfaces 330r1 and/or 330r2 to engage with the opening 330r and allow the bottom surface of the protrusion 330P to contact and abut against the upper surface 211 of the photonic component 21. The protrusion 330P may be made of a material the same as or different from that of the base 300s. In some arrangements, the base 300s is made of or includes glass, and the protrusion 330P is made of or includes a photoresist material.

The extension 340 may define an opening similar to the opening 330r, and the photonic component 22 may include a protrusion similar to the protrusion 210P to engage with the opening of the extension 340.

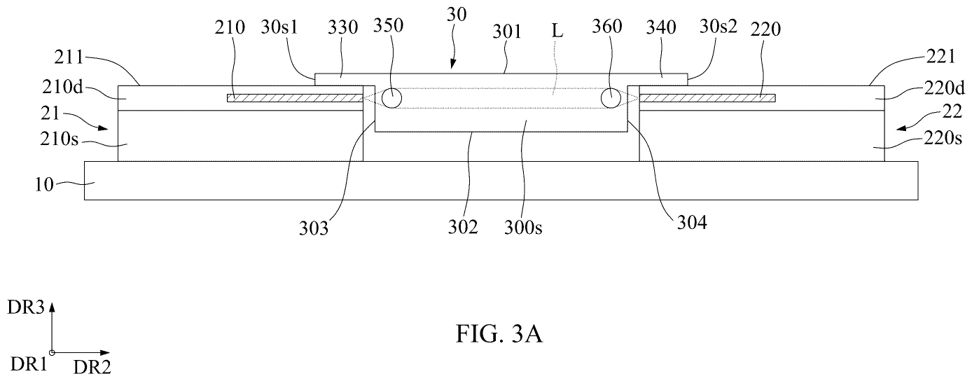

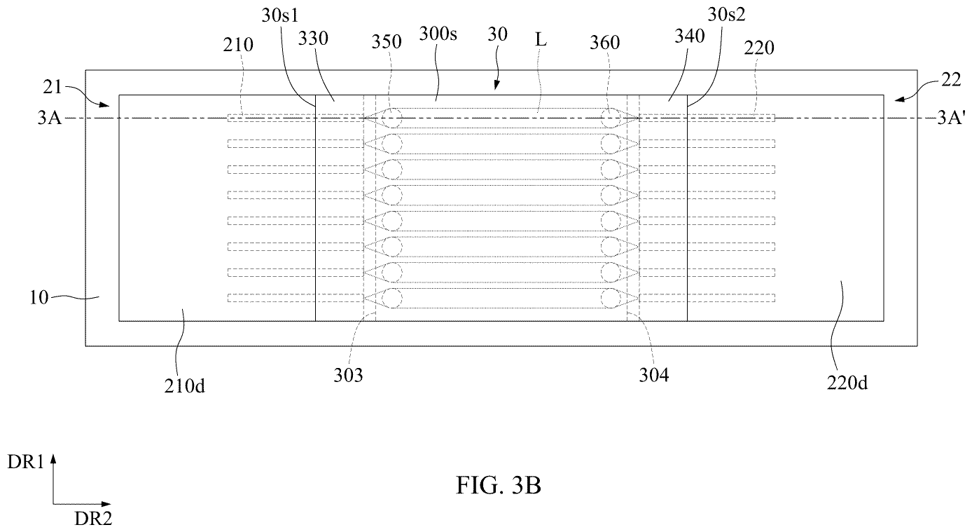

FIG. 3A is a cross-section of a package structure 3 in accordance with some arrangements of the present disclosure. FIG. 3B is a top view of a package structure 3 in accordance with some arrangements of the present disclosure. In some arrangements, FIG. 3A is a cross-section along a line 3A-3A′ in FIG. 3B. The package structure 3 is similar to the package structure 1 in FIGS. 1A-1B, and the differences therebetween are described as follows.

In some arrangements, the package structure 3 includes doped regions 350 and 370 integrated within the homogeneous medium (e.g., the base 300s). The doped regions 350 and 370 may be referred to as optical structures of the optical connector 30. In some arrangements, the doped regions 350 and 370 have a refractive index higher than a refractive index of the homogeneous medium (e.g., the base 300s). In some arrangements, a difference in the refractive indexes of the doped regions 350 and 370 and the base 300s is greater than 0.018. The difference in the refractive indexes of the doped regions 350 and 370 and the base 300s is from about 0.018 to about 0.08. In some arrangements, the doped regions 350 (or the optical structure) include a collimation optics, a focusing optics, or a combination thereof. In some arrangements, the doped regions 370 (or the optical structure) include a collimation optics, a focusing optics, or a combination thereof. In some arrangements, the doped regions 350 and 370 are configured to focus the optical signals L from the homogeneous medium (e.g., the base 300s) to transmit the focused optical signals L to the optical channels 210 and 220, respectively. In some arrangements, the doped regions 350 and 370 are configured to collimate the optical signals L from the optical channels 210 and 220, respectively, to transmit the collimated optical signals L to the homogeneous medium (e.g., the base 300s).

In some arrangements, the base 300s is or includes glass, and the doped regions 350 and 370 include silver ions (Ag⁺), potassium ions (K⁺), thallium ions (Tl⁺), or a combination thereof. The base 300s may be made of an amorphous material including SiO₂, GeO₂, or P₂O₅ and sodium ions (Na⁺), and portions of the base 300s may be ion-exchanged to replace the sodium ions (Na⁺) with silver ions (Ag⁺), potassium ions (K⁺), and/or thallium ions (Tl⁺) to form the doped regions 350 and 370. In some arrangements, a masking layer may be disposed over the surface of the base 300s to expose partially regions that allow silver ions (Ag⁺), potassium ions (K⁺), and/or thallium ions (Tl⁺) to diffuse into the base 300s. The masking layer may be removed after the ion-exchange is completed. In some arrangements, an electric field is applied to push the doped ions to further diffuse into the base 300s so as to form the doped regions 350 and 370 that are embedded in the base 300s. The exact positions of the doped regions 350 and 370 may depend on the parameters of the applied electric field. The doped regions 350 and 370 may be detected or observed by an optical microscope, in which the base 300s and the doped regions 350 and 370 show different colors. For example, the base 300s made of a glass is in light blue, and the doped regions 350 and 370 including silver ions (Ag⁺) are in pink. The images may be observed with an InGaAs Camera at λ=1.5 μm.

In some arrangements, the doped regions 350 and 370 have ball shapes. In some arrangements, the doped regions 350 and 370 are or include ball lenses. The doped regions 350 and arranged in a row in the direction DR1, and the doped regions 370 are arranged in a row in the direction DR1. In some arrangements, one optical channel 210, one doped region 350, one doped region 370, and one optical channel 220 are aligned along the direction DR2. In some arrangements, one optical channel 210, one doped region 350, one doped region 370, and one optical channel 220 overlap as viewed in the direction DR2.

According to some arrangements of the present disclosure, the optical structures of the optical connector 30 include doped regions 350 and 370 facing the photonic components 21 and 22, respectively, and are configured to optically couple the photonic components 21 and 22. The optically coupling surfaces of the optical connector 30 are lateral surfaces 303 and 304 that are substantially flat compared to convex curved lenses, the distance between the photonic components 21 and 22 can be reduced, and thus the optical transmission path between the photonic components 21 and 22 can be reduced, which is advantageous to increasing the transmission speed.

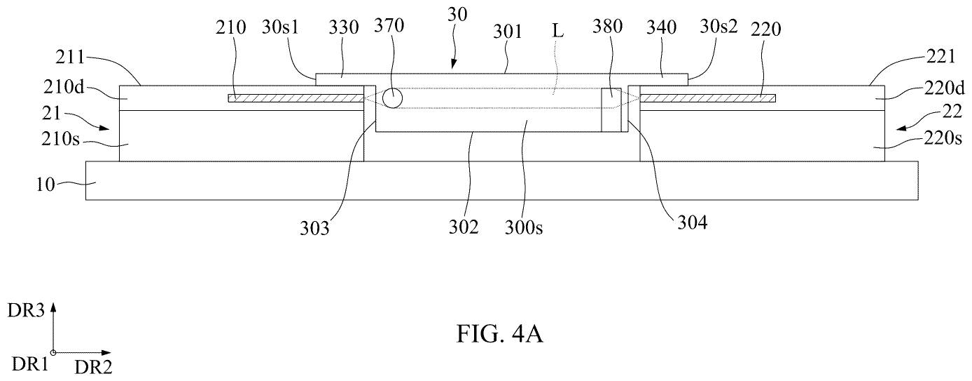

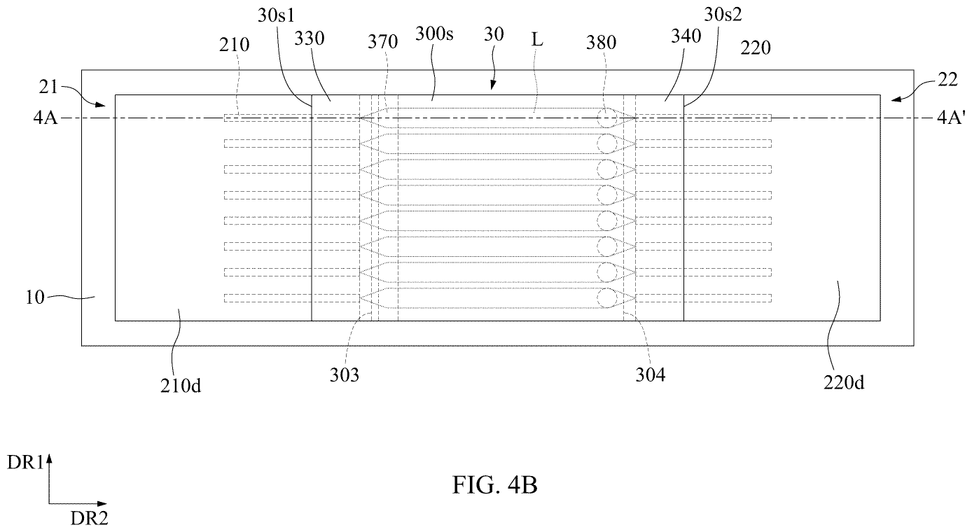

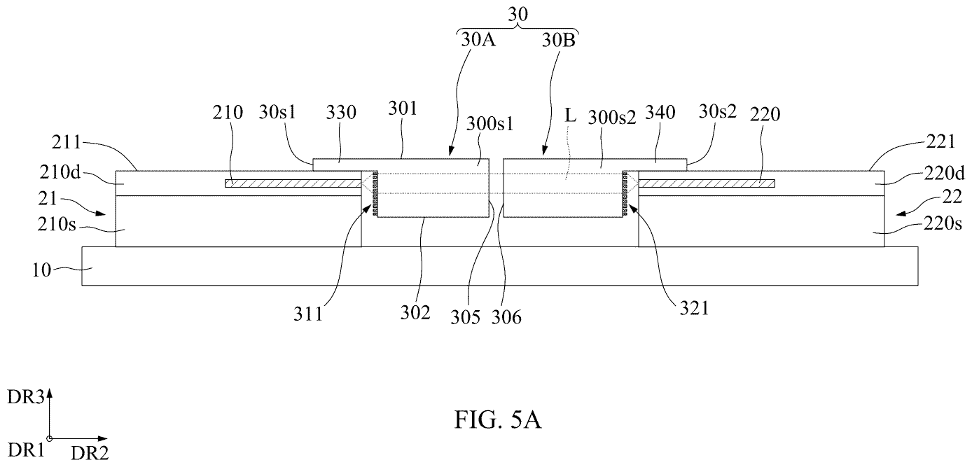

FIG. 4A is a cross-section of a package structure 4 in accordance with some arrangements of the present disclosure. FIG. 4B is a top view of a package structure 4 in accordance with some arrangements of the present disclosure. In some arrangements, FIG. 4A is a cross-section along a line 4A-4A′ in FIG. 4B. The package structure 4 is similar to the package structure 1 in FIGS. 1A-1B and/or the package structure 3 in FIGS. 3A-3B, and the differences therebetween are described as follows.

In some arrangements, the doped region 370 includes a pillar shape and extends in the direction DR1. In some arrangements, each of the doped regions 380 includes a pillar shape, and the doped regions 380 extend in the direction DR3 substantially perpendicular to the direction DR1. In some arrangements, the doped region 370 overlaps the optical channels 210 and the doped regions 380 as viewed in the direction DR2. In some arrangements, each of the doped regions 380 overlaps a corresponding optical channel 220 as viewed in the direction DR2.

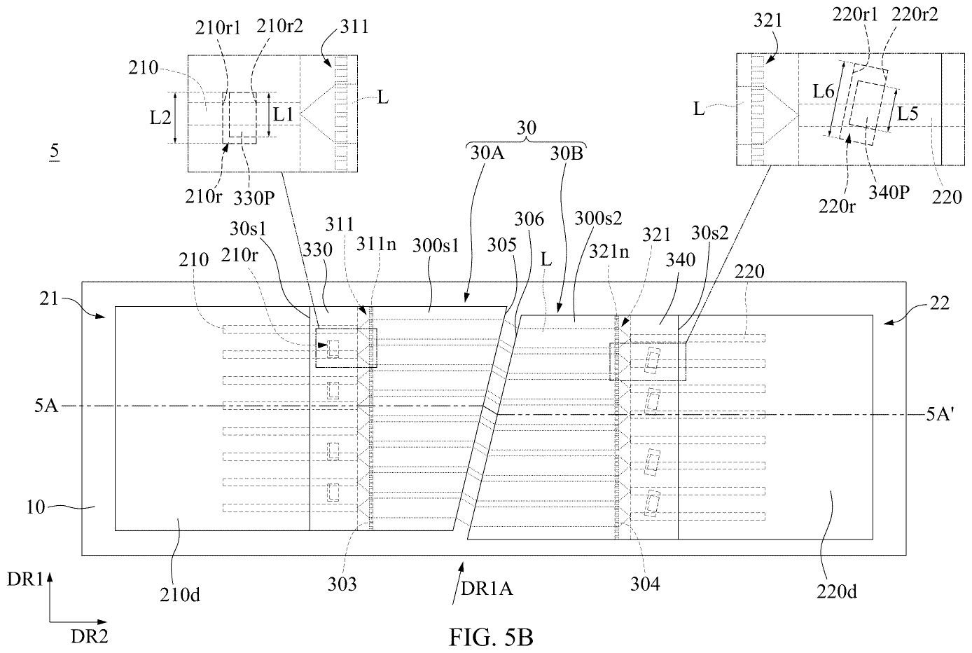

FIG. 5A is a cross-section of a package structure 5 in accordance with some arrangements of the present disclosure. FIG. 5B is a top view of a package structure 5 in accordance with some arrangements of the present disclosure. In some arrangements, FIG. 5A is a cross-section along a line 5A-5A′ in FIG. 5B. The package structure 5 is similar to the package structure 1 in FIGS. 1A-1B, the package structure 3 in FIGS. 3A-3B, and/or the package structure 4 in FIGS. 4A-4B, and the differences therebetween are described as follows.

In some arrangements, the photonic component 21 is misaligned with the photonic component 22. In some arrangements, at least one of the optical channels 210 is misaligned with at least one of the optical channels 220. In some arrangements, the optical channels 210 are misaligned with the optical channels 220.

In some arrangements, the optical connector 30 includes a portion 30A and a portion 30B spaced apart from the portion 30A. In some arrangements, the portion 30A includes an optical structure (e.g., the metasurface structure 311) facing the photonic component 21, and the portion 30B includes an optical structure (e.g., the metasurface structure 321) facing the photonic component 22. In some arrangements, the portion 30A is configured to focus or collimate the optical signal L between the optical channel 210 and the optical channel 220. In some arrangements, the portion 30B is configured to focus or collimate the optical signal L between the optical channel 210 and the optical channel 220. In some arrangements, each of the optical structures (e.g., the metasurface structures 311 and 321) of the portions 30A and 30B includes a collimation optics, a focusing optics, or a combination thereof.

In some arrangements, the portion 30A includes a surface 305 facing the portion 30B, and the portion 30B includes a surface 306 facing and substantially parallel to the surface 305. In some arrangements, the metasurface (e.g., the metasurface structure 311) of the portion 30A is non-parallel to the surface 305. In some arrangements, the optically coupling surface (e.g., the lateral surface 303) of the portion 30A is non-parallel to the surface 305. In some arrangements, the surfaces 305 and 306 extend in a direction DR1A that is non-parallel to the direction DR1 and the direction DR2. In some arrangements, the metasurface (e.g., the metasurface structure 321) of the portion 30B is non-parallel to the surface 306. In some arrangements, the optically coupling surface (e.g., the lateral surface 304) of the portion 30B is non-parallel to the surface 306.

In some arrangements, the portion 30A includes a homogeneous base 300s1 connected to the metasurface structure 311, and the portion 30B includes a homogeneous base 300s2 connected to the metasurface structure 321. In some arrangements, the extension 330 is connected to the homogeneous base 300s1, and the extension 340 is connected to the homogeneous base 300s2. The portion 30A including the homogeneous base 300s1 and the extension 330 may be a monolithic structure or an integral piece, e.g., formed integrally. The portion 30B including the homogeneous base 300s2 and the extension 340 may be a monolithic structure or an integral piece, e.g., formed integrally. In some arrangements, the homogeneous base 300s1 and the extension 330 as a whole may have a substantially uniform refractive index. In some arrangements, the homogeneous base 300s2 and the extension 340 as a whole may have a substantially uniform refractive index. In some arrangements, the homogeneous base 300s1 and the extension 330 as a whole may be an integral layer (or a monolithic structure) and free of any optical waveguide formed or disposed therewithin. In some arrangements, the homogeneous base 300s2 and the extension 340 as a whole may be an integral layer (or a monolithic structure) and free of any optical waveguide formed or disposed therewithin.

In some arrangements, referring to FIG. 5B, the extension 340 includes a protrusion 340P, and the photonic component 22 includes a recess 220r configured to engage with the protrusion 340P. The dielectric structure 220d may define the recess 220r. In some arrangements, a length L5 of the protrusion 340P is less than a length L6 of the recess 220r. In some arrangements, a difference in the length L6 of the recess 220r and the length L5 of the protrusion 340P is greater than a difference in the length L2 of the recess 210r and the length L1 of the protrusion 330P. In some arrangements, a lateral side of the recess 220r is non-parallel to the metasurface (e.g., the metasurface structure 321). In some arrangements, a lateral side of the recess 220r is non-parallel to the lateral surface 304.

According to some arrangements of the present disclosure, when the photonic components 21 and 22 are misaligned to each other due to alignment errors during the manufacturing process of the package structure 5, the optical connector 30 includes the portions 30A and 30B that are spaced apart from each other and having the surfaces 305 and 306 substantially parallel to each other. The surfaces 305 and 306 are inclined with respect to the optically coupling surfaces (e.g., the metasurfaces or the lateral surfaces 303 and 304) of the optical connector 30, and the optical signals L from the optical channels 210 may be refracted at the surface 305 and exits the surface 305, then the optical signals L enter the surface 306 and are refracted again. As such, after the portion 30A is disposed on the photonic component 21, the portion 30B can be shifted to an adjusted position along the direction DR1 so as to allow the optical signals L from the optical channels 210 to be refracted twice in the process of passing the surfaces 305 and 306 to be transmitted to the optical channels 220 that are misaligned with the optical channels 210. Therefore, with the above design, the optical signals L can be transmitted between the misaligned optical channels 210 and 220.

In addition, according to some arrangements of the present disclosure, the difference in the length L6 of the recess 220r and the length L5 of the protrusion 340P is greater than the difference in the length L2 of the recess 210r and the length L1 of the protrusion 330P. Therefore, a relatively large space for the protrusion 340P to move or shift along the direction DR1A, allowing the portion 30B to move to the adjusted position so as to guide the optical signals L to transmit from the optical channels 210 to the optical channels 220.

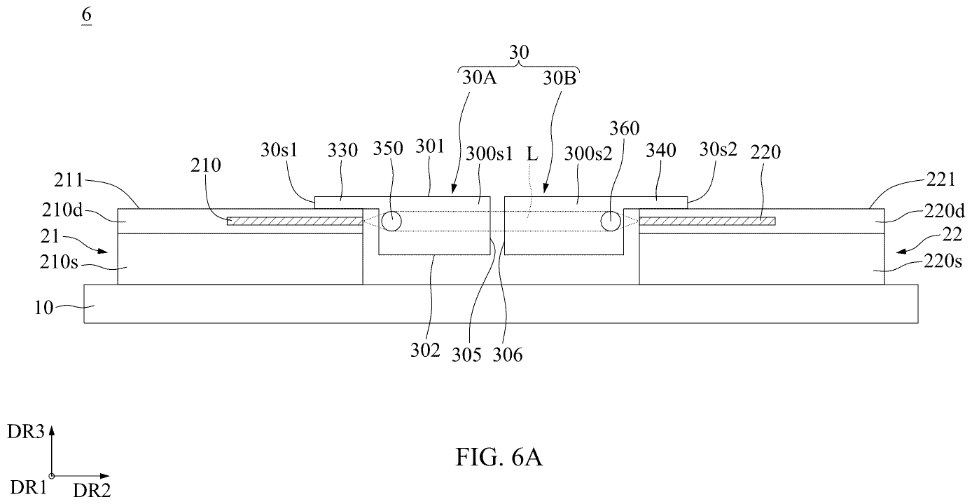

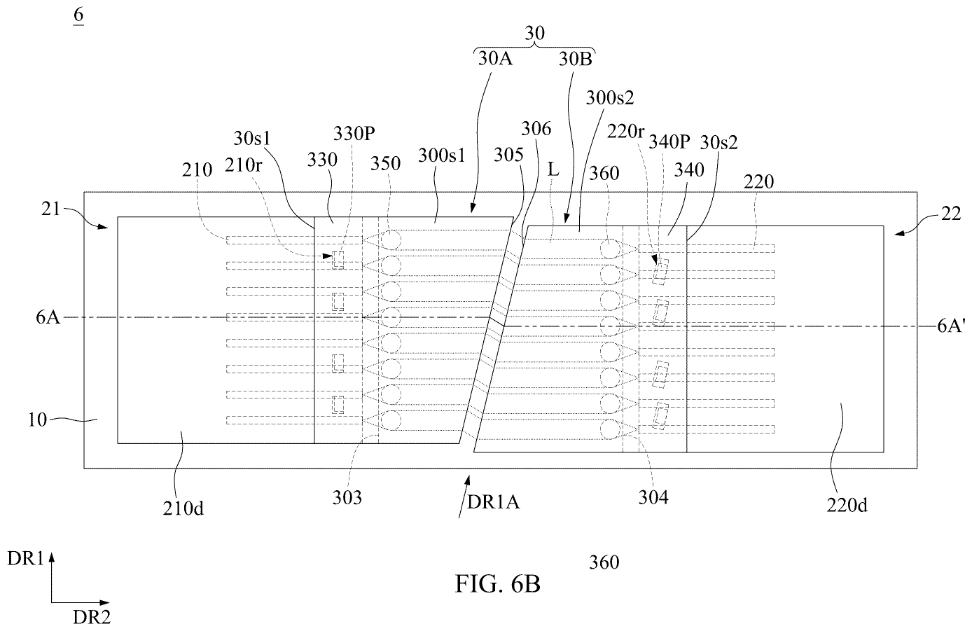

FIG. 6A is a cross-section of a package structure 6 in accordance with some arrangements of the present disclosure. FIG. 6B is a top view of a package structure 6 in accordance with some arrangements of the present disclosure. In some arrangements, FIG. 6A is a cross-section along a line 6A-6A′ in FIG. 6B. The package structure 6 is similar to the package structure 1 in FIGS. 1A-1B, the package structure 3 in FIGS. 3A-3B, the package structure 4 in FIGS. 4A-4B, and/or the package structure 5 in FIGS. 5A-5B, and the differences therebetween are described as follows.

In some arrangements, the package structure 6 includes doped regions 350 and 370, and the doped regions 350 are misaligned with the doped regions 370. In some arrangements, the optical channels 220 are misaligned with the optical channels 210, the doped regions 350 are substantially aligned with the optical channels 210, and the doped regions 370 are substantially aligned with the optical channels 220.

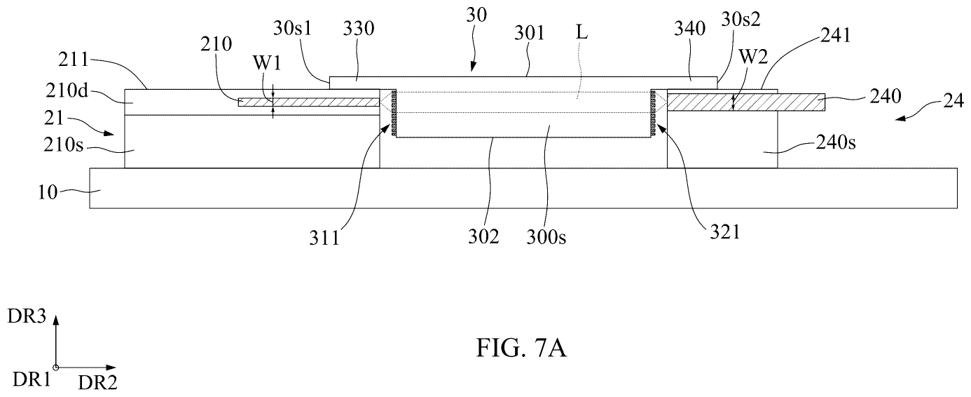

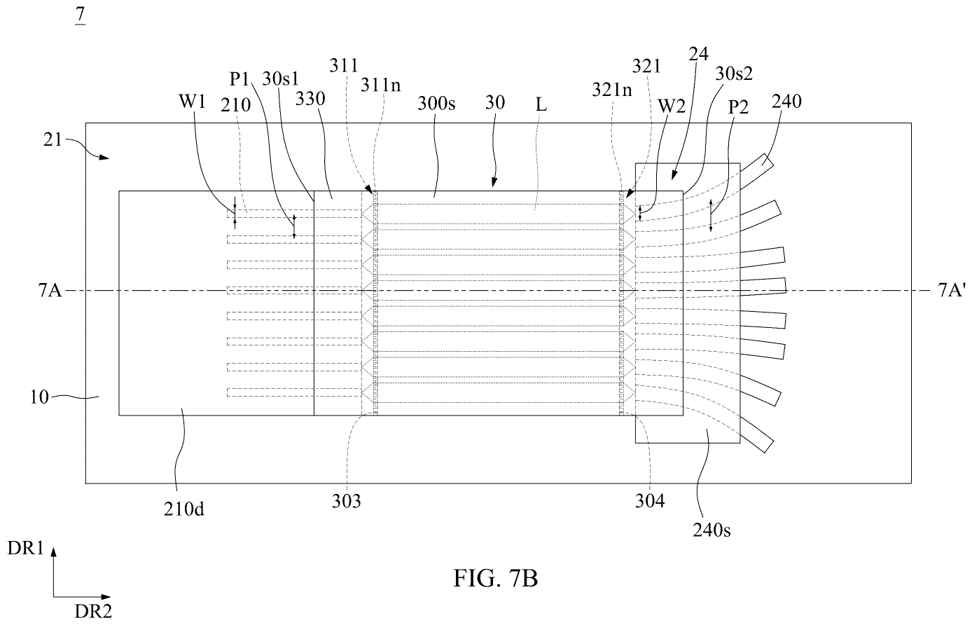

FIG. 7A is a cross-section of a package structure 7 in accordance with some arrangements of the present disclosure. FIG. 7B is a top view of a package structure 7 in accordance with some arrangements of the present disclosure. In some arrangements, FIG. 7A is a cross-section along a line 7A-7A′ in FIG. 7B. The package structure 7 is similar to the package structure 1 in FIGS. 1A-1B, the package structure 3 in FIGS. 3A-3B, the package structure 4 in FIGS. 4A-4B, the package structure 5 in FIGS. 5A-5B, and/or the package structure 6 in FIGS. 6A-6B, and the differences therebetween are described as follows.

In some arrangements, the package structure 7 includes an optical component 24 configured to optically couple to the photonic component 21. In some arrangements, the optical component 24 includes a base 240s and a plurality of optical channels 240 partially disposed in the base 240s. In some arrangements, the extension 340 of the optical connector 30 is supported by an upper surface 241 of the optical component 24. In some arrangements, a width W1 of the optical channels 210 is less than a width W2 of the optical channels 240. In some arrangements, a pitch P1 of the optical channels 210 is less than a pitch P2 of the optical channels 220. In some arrangements, the optical channels 240 are or include optical fibers, and the optical component 24 is or includes a fiber array unit (FAU).

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package structure, comprising:
a first photonic component;
a second photonic component; and
an optical connector comprising a first metasurface and a second metasurface opposite to the first metasurface and configured to optically couple the first photonic component to the second photonic component.

2. The package structure as claimed in claim 1, wherein the optical connector comprises a transparent base configured to transmit a plurality of optical signals between the first photonic component and the second photonic component.

3. The package structure as claimed in claim 2, wherein the optical connector further comprises a first extension supported by the first photonic component and a second extension supported by the second photonic component.

4. The package structure as claimed in claim 3, wherein the first extension comprises a first protrusion, and the first photonic component comprises a first recess configured to engage with the first protrusion.

5. The package structure as claimed in claim 4, wherein the second extension comprises a second protrusion, and the second photonic component comprises a second recess configured to engage with the first protrusion.

6. The package structure as claimed in claim 5, wherein a difference in a length of the second recess and a length of the second protrusion is greater than a difference in a length of the first recess and a length of the first protrusion.

7. The package structure as claimed in claim 4, wherein a lateral side of the first recess is non-parallel to the first metasurface.

8. The package structure as claimed in claim 3, wherein the first extension defines an opening, and the first photonic component comprises a protrusion configured to engage with the opening.

9. A package structure, comprising:
a first photonic component comprising a first optical channel;
a second photonic component comprising a second optical channel misaligned with the first optical channel; and
an optical connector comprising a first optical structure and a second optical structure each being configured to focus or collimate an optical signal transmitted between the first optical channel and the second optical channel.

10. The package structure as claimed in claim 9, wherein the optical connector comprises a first portion comprising the first optical structure and a second portion comprising the second optical structure and spaced apart from the first portion.

11. The package structure as claimed in claim 10, wherein the first portion further comprises a first homogeneous base connected to the first optical structure, and the second portion comprises a second homogeneous base connected to the second optical structure.

12. The package structure as claimed in claim 10, wherein a first surface of the first portion is facing and substantially parallel to a second surface of the second portion, and the first optical structure comprises a metasurface facing the first photonic component and non-parallel to the first surface.

13. The package structure as claimed in claim 10, wherein the first optical structure comprises a first doped region configured to focus or collimate the optical signal, and the second optical structure comprises a second doped region misaligned with the first doped region and configured to focus or collimate the optical signal.

14. The package structure as claimed in claim 10, wherein the first photonic component comprises a plurality of the first optical channels, the second photonic component comprises a plurality of second optical channels misaligned with the first optical channels, the first optical structure comprises a plurality of first doped regions substantially aligned with the first optical channels, and the second optical structure comprises a plurality of second doped regions substantially aligned with the second optical channels.

15. A package structure, comprising:
a first optical component;
a second optical component; and
an optical connector comprising a homogeneous medium configured to transmit a plurality of optical signals between the first optical component and the second optical component.

16. The package structure as claimed in claim 15, wherein the homogeneous medium is free of an optical waveguide.

17. The package structure as claimed in claim 15, wherein the homogeneous medium has a first substantially flat coupling surface facing the first optical component and a second substantially flat coupling surface facing the second optical component.

18. The package structure as claimed in claim 15, wherein the first optical component comprises a plurality of first optical channels configured to transmit the optical signals to or from the homogeneous medium, and the second optical component comprises a plurality of second optical channels configured to transmit the optical signals to or from the homogeneous medium.

19. The package structure as claimed in claim 18, wherein a width of the first optical channels is less than a width of the second optical channels.

20. The package structure as claimed in claim 18, wherein a pitch of the first optical channels is less than a pitch of the second optical channels.
